(19) United States
(12) Patent Application Publication
(10) Pub. No.: US 2014/0022721 A1
(43) Pub. Date: Jan. 23, 2014

(54) ELECTRONIC DEVICE ENCLOSURE

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: LIANG-CHIN WANG, New Taipei (TW); YU-MING XIAO, Wuhan (CN); LIN DING, Wuhan (CN); CONG TANG, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/873,208

(22) Filed: Apr. 29, 2013

(30) Foreign Application Priority Data
Jul. 23, 2012 (CN) 2012102545723

(51) Int. Cl. H05K 7/14

(52) U.S. Cl. CPC H05K 7/14
USPC 361/679.32

(57) ABSTRACT

An electronic device apparatus includes an enclosure and a pressing assembly pivotally mounted in the enclosure. A circuit board is mounted in the enclosure. A bottom edge of an expansion card is mounted on the circuit board. The pressing assembly includes a flexible and elastic pressing member. The pressing member includes a pressing portion and a pair of securing feet mounted on opposite edges of the pressing portion. A distance of the pair of securing feet is larger than a with of a top edge of the expansion card. The top edge of the expansion card is located between the pair of securing feet and is pressed by the pressing portion.

### BACKGROUND

1. Technical Field

The present disclosure relates to an enclosure for an electronic device, and particularly to an enclosure accepting an expansion card.

2. Description of Related Art

Increasing numbers of electronic devices utilize different expansion cards mounted therein. The expansion cards can easily loosen in the enclosure especially when transported, which can impair the proper function and also damage the electronic device.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device enclosure.

FIG. 2 is an exploded, isometric view of a pressing assembly of the electronic device enclosure of FIG. 1.

FIG. 3 is an assembled view of the electronic device enclosure of FIG. 1.

FIG. 4 is another assembled view of the electronic device enclosure of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

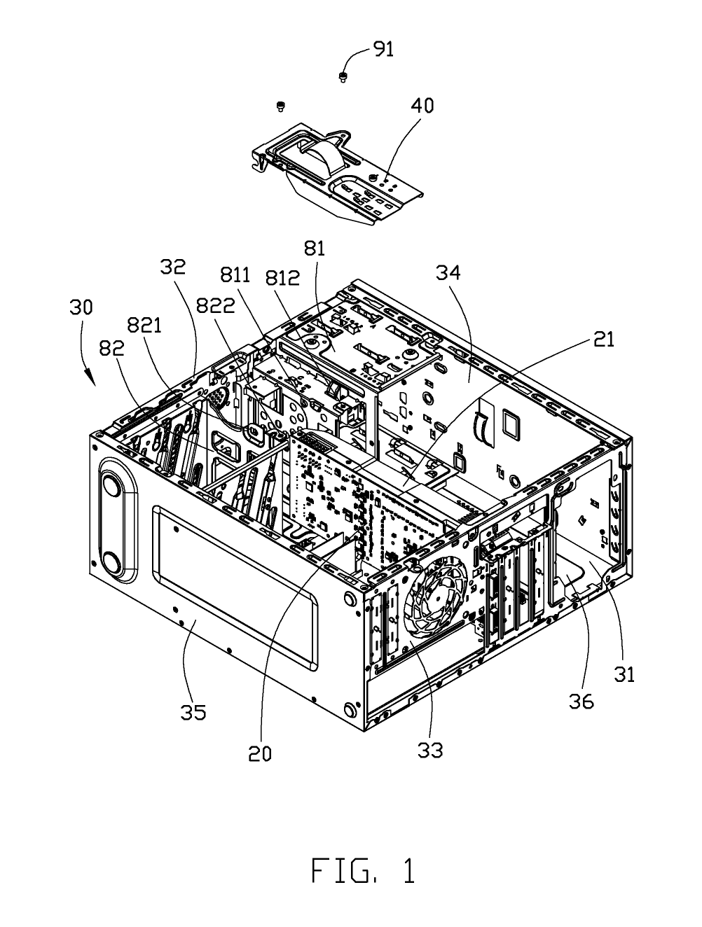

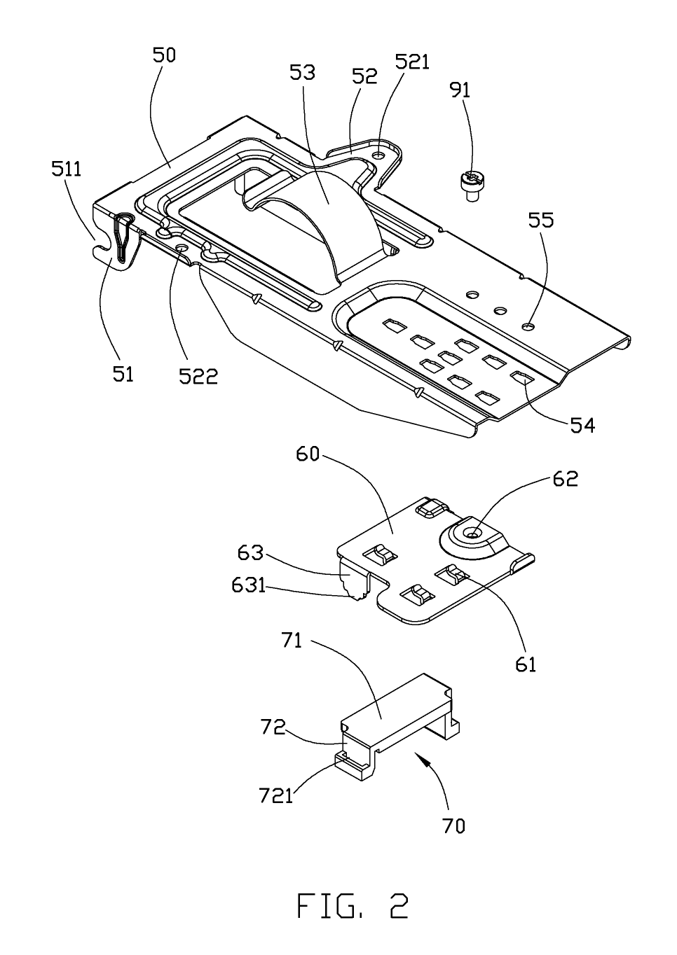

FIGS. 1 and 2 show an electronic device enclosure in accordance with an embodiment. The electronic device enclosure includes an enclosure 30 and a pressing assembly 40. An expansion card 20 can be secured in the enclosure 30 firmly.

The enclosure 30 includes a bottom plate 31, a front plate 32, a rear plate 33, a first side plate 34, and a second side plate 35. The front plate 32, the rear plate 33, the first side plate 34, and the second side plate 35 are substantially perpendicular and connected to edges of the bottom plate 31. The front plate 32 is substantially parallel to the rear plate 33. The first side plate 34 is substantially parallel to the second side plate 35. The front plate 32 is substantially perpendicular to the rear plate 33. A circuit board 36 is mounted on the bottom plate 31. The circuit board 36 defines a plurality of expansion slots (not shown).

The enclosure 30 includes a first drive bracket 81 and a second drive bracket 82 mounted on the front plate 32. The first drive bracket 81 is located adjacent the first side plate 34. The second drive bracket 82 is located adjacent the second side plate 35. A receiving space is defined between the first drive bracket 81 and the second drive bracket 82. A side of the first drive bracket 81 which faces the second drive bracket 82, forms a first protrusion 811. A side of the second drive bracket 82 which faces the first drive bracket 81, forms a second protrusion 821. The first drive bracket 81 defines a first mounting hole 812. The second drive bracket 82 defines a second mounting hole 822.

A bottom edge of the expansion card 20 defines a connector and is inserted in one expansion slot of the circuit board 36. The expansion card 20 includes a top edge 21.

FIG. 2 shows that the pressing assembly 40 includes a rotating piece 50, an attaching piece 60, and a pressing member 70. The rotating piece 50 includes a pair of bent pieces 51 substantially perpendicular and connected to the rotating piece 50. Each of the pair of bent pieces 51 defines a pivoting slot 511. A securing piece 52 is connected to the rotating piece 50. The securing piece 52 defines a first through hole 521 corresponding to the first mounting hole 812. The rotating piece 50 defines a second through hole 522 corresponding to the second mounting hole 822. A middle portion of the rotating piece 50 forms a handle 53 for conveniently rotating the rotating piece 50. A rear portion of the rotating piece 50 defines a plurality of engaging holes 54 and a plurality of securing holes 55.

The attaching piece 60 can be mounted below the rotating piece 50. The attaching piece 60 forms a plurality of clasps and a second securing hole 62. A pair of clip pieces 63 extends downwardly from the attaching piece 60. The clip piece 63 can be elastically deformed. A distal end of the clip piece 63 forms an inserting end 631.

The pressing member 70 is an “n”-shaped bent piece, which includes a pressing portion 71 and a pair of securing feet 72 connected to opposite edges of the pressing portion 71. A distance between the pair of securing feet 72 is larger than a width of the top edge 21 of the expansion card 20. The top edge 21 can be located between the pair of securing feet 72 and pressed by the pressing portion 71. Each securing foot 72 defines a securing slot 721. The pressing member 70 is made of flexible and elastic material, such as rubber.

To assemble the pressing assembly 40, the inserting ends 631 of the pair of clip pieces 63 of the attaching piece 60 is inserted in the securing slots 721 of the pressing member 70. Simultaneously, the pair of clip pieces 63 sandwiches the securing feet 72 to mount the pressing member 70 on the attaching piece 60. The clasps 61 of the attaching piece 60 engage in the engaging hole 54 of the rotating piece 50. The second securing hole 62 is aligned to one first securing hole 55. Because the rotating piece 50 defines a plurality of engaging holes 55, the clasps 61 can be engaged in different engaging holes 54 to mount the attaching piece 60 on different positions of the rotating piece 50.

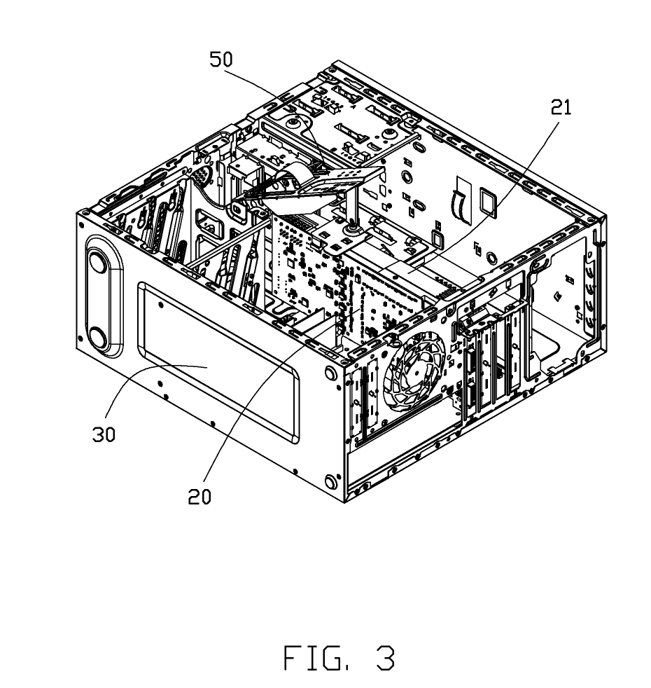

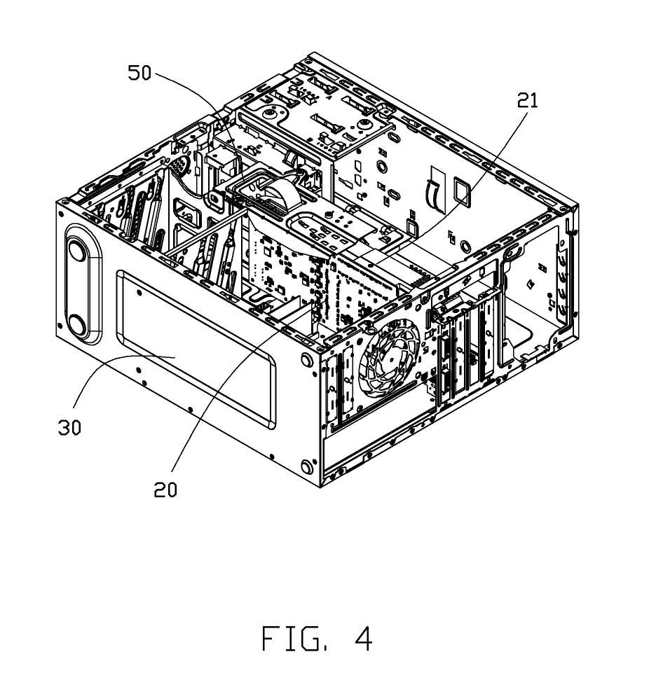

FIGS. 1 to 4 show that when mounting the pressing assembly 40 on the rotating piece 50, the first protrusion 811 and the second protrusion 821 are located in the pivoting slots 511 of the rotating piece 50 to pivotally mount the rotating piece 50 in the enclosure 30 and rotate. The top edge 21 of the expansion card 20 is located between the pair of securing feet 72. The pressing portion 71 is pressed on the top edge 21 to firmly mount the expansion card 20 in the enclosure 30. At this position, the first through hole 521 of the rotating piece 50 is aligned with the first mounting hole 812 of the first drive bracket 81, and the second through hole 522 of the rotating piece 50 is aligned with the second mounting hole 822 of the second drive bracket 82. The two screws 91 are mounted in the first through hole 521, the first mounting hole 812, the second through hole 522, and the second mounting hole 822 to secure the rotating piece 50 on the first drive bracket 81 and the second drive bracket 82.

In the above embodiment, because the pressing member 70 is made of flexible and elastic material, when the enclosure is impacted, the pressing member 70 can elastically deform to absorb the impact to protect the expansion card 20 from damage.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device apparatus, comprising:
an enclosure;
a circuit board mounted in the enclosure;
an expansion card having a bottom edge mounted on the circuit board; and
a pressing assembly pivotally mounted in the enclosure, the pressing assembly comprising a flexible and elastic pressing member, the pressing member comprising a pressing portion and a pair of securing feet mounted on opposite edges of the pressing portion, a distance of the pair of securing feet being larger than a with of a top edge of the expansion card, wherein the top edge of the expansion card is located between the pair of securing feet and is pressed by the pressing portion.

2. The electronic device apparatus of claim 1, wherein the pressing assembly further comprises a rotating piece and an attaching piece, the rotating piece is pivotally mounted on the enclosure, and the attaching piece attaches the pressing member on the rotating piece.

3. The electronic device apparatus of claim 2, wherein the enclosure comprises a first drive bracket and a second drive bracket mounted therein, the first drive bracket comprises a first protrusion, the second drive bracket comprises a second protrusion, the rotating piece comprises a pair of bent pieces, the pair of bent pieces defines a pair of pivoting slots, and the first protrusion and the second protrusion are pivotally received in the pair of pivoting slots.

4. The electronic device apparatus of claim 2, wherein the attaching piece comprises a plurality of clasps, the rotating piece defines a plurality of engaging holes, and the plurality of clasps is engaged in the plurality of engaging holes.

5. The electronic device apparatus of claim 4, wherein the attaching piece defines a plurality of first securing holes, the attaching piece defines a second securing hole, and the plurality of clasps is configured to engage in different engaging holes of the plurality of engaging holes to align the second securing hole with different first securing holes to mount the attaching piece on different positions of the rotating piece.

6. The electronic device apparatus of claim 2, wherein the attaching piece comprises a pair of clip pieces, and the pressing member is sandwiched by the pair of clip pieces.

7. The electronic device apparatus of claim 6, wherein a distal end of each of the pair of clip pieces comprises an inserting end, each of the pair of feet defines a securing slot, and the inserting end is inserted in the securing slot.

8. An electronic device apparatus, comprising:
an enclosure;
a circuit board mounted in the enclosure;
an expansion card mounted on the circuit board;
a first drive bracket and a second drive bracket mounted in the enclosure; and
a pressing assembly pivotally mounted between the first drive bracket and the second drive bracket, the pressing assembly comprising a pressing member, the pressing member comprising a pressing portion and a pair of securing feet mounted on opposite edges of the pressing portion, wherein the pair of securing feet sandwiches the expansion card, and the pressing portion presses the expansion card on the circuit board.

9. The electronic device apparatus of claim 8, wherein a bottom edge of the expansion card is mounted on the circuit board, and a top edge of the expansion card is pressed by the pressing portion.

10. The electronic device apparatus of claim 8, wherein the pressing assembly further comprises a rotating piece and an attaching piece, the rotating piece is pivotally mounted on the enclosure, and the attaching piece attaches the pressing member on the rotating piece.

11. The electronic device apparatus of claim 10, wherein the first drive bracket comprises a first protrusion, the second drive bracket comprises a second protrusion, the rotating piece comprises a pair of bent pieces, the pair of bent pieces defines a pair of pivoting slots, and the first protrusion and the second protrusion are pivotally received in the pair of pivoting slots.

12. The electronic device apparatus of claim 10, wherein the attaching piece comprises a plurality of clasps, the rotating piece defines a plurality of engaging holes, and the plurality of clasps is engaged in the plurality of engaging holes.

13. The electronic device apparatus of claim 12, wherein the attaching piece defines a plurality of first securing holes, the attaching piece defines a second securing hole, and the plurality of clasps is configured to engage in different engaging holes of the plurality of engaging holes to align the second securing hole with different first securing holes to mount the attaching piece at different positions of the rotating piece.

14. The electronic device apparatus of claim 10, wherein the attaching piece comprises a pair of clip pieces, and the pressing member is sandwiched by the pair of clip pieces.

15. The electronic device apparatus of claim 14, wherein a distal end of each of the pair of clip pieces comprises an inserting end, each of the pair of feet defines a securing slot, and the inserting end is inserted in the securing slot.
